(19) United States
(12) Patent Application Publication
(10) Pub. No.: US 2025/0334646 A1
(43) Pub. Date: Oct. 30, 2025

(54) VOLTAGE BASED BATTERY CELL FAULT DETECTION

(71) Applicant: Infineon Technologies AG, Neubiberg (DE)

(72) Inventors: Norbert SAILER, Graz (AT); Christoph STEFFAN, Fraham (AT)

(21) Appl. No.: 18/644,371

(22) Filed: Apr. 24, 2024

(51) Int. Cl. G01R 31/396; G01R 31/385; G01R 31/389; G01R 31/392

(52) U.S. Cl. CPC G01R 31/396; G01R 31/385; G01R 31/392; G01R 31/389

(57) ABSTRACT

Techniques for identifying degraded or faulty battery cells of a battery stack are described. A controller measures cell voltages of a plurality of N battery cells arranged in series with one another in a battery stack. The controller arranges the plurality of N battery cells into subsets. The controller determines a metric across each of the subsets based on the measured cell voltages. The controller compares the metric of a battery cell subset to the metrics of other subsets. The controller identifies a degraded or faulty battery cell based on the comparison.

### TECHNICAL FIELD OF THE INVENTION

This invention relates generally to battery system, and more specifically to techniques for monitoring battery cells of a battery stack.

### BACKGROUND

Many electrical devices, from small devices like portable power tools to large devices like electric or hybrid vehicles (i.e., battery electric vehicles (BEV)), use battery cells arranged in a battery stack as a power source. In some examples, some battery cells of a battery stack may become faulty over time. A faulty or degraded battery cell may impact performance of a battery to store and/or supply energy. A faulty or degraded battery cell may also explode, catch fire, or otherwise risk damage to a vehicle or safety of vehicle occupants. As such, it may be important to detect defective and/or faulty battery cells and mitigate any potential impact, for example by ceasing to use the defective or faulty cell to store and/or deliver energy.

In some examples, traditional battery controllers are configured to detect defective or faulty battery cells by injecting a relatively large known current through a battery stack to measure an impedance of each cell based on the known current, which may expend a significant amount of energy. A need exists for improvements in battery controllers to identify degraded and/or faulty battery cells with reduced power usage, complexity, and/or cost to implement in comparison with traditional battery controllers.

### SUMMARY

According to one example, in some aspects, a method is described. The method includes measuring cell voltages of a plurality of N battery cells arranged in series with one another in a battery stack. The method further includes arranging the plurality of N battery cells into subsets. The method further includes determining a metric across each of the subsets based on the measured cell voltages. The method further includes comparing the metric of a subset to metrics across other subsets. The method further includes identifying a degraded or faulty battery cell of the subset based on the comparing.

According to another example, in some aspects, a battery controller is configured to measure cell voltages of a plurality of N battery cells arranged in series with one another in a battery stack. The battery controller is further configured to arrange the plurality of N battery cells into subsets. The battery controller is further configured to determine a metric across each of the subsets based on the measured cell voltages. The battery controller is further configured compare the metric across a subset to metrics across other subsets. The battery controller is further configured to identify a degraded or faulty battery cell of the subset based on the comparison.

According to another example, in some aspects, a non-transitory computer-readable medium is configured to store instructions that cause a controller to measure cell voltages of a plurality of N battery cells arranged in series with one another in a battery stack. The instructions are further configured to cause the controller to arrange the plurality of N battery cells into subsets. The instructions are further configured to cause the controller to determine a metric across each of the subsets based on the measured cell voltages. The instructions are further configured to cause the controller to compare a metric of a battery cell subset to metrics across other subsets. The instructions are further configured to cause the controller to identify a degraded or faulty battery cell of the subset based on the comparison.

### BRIEF DESCRIPTION OF THE DRAWINGS

The present invention will now be described, by way of example with reference to the accompanying drawings, in which:

FIG. 1 is a block diagram that depicts one example of a battery system according to some embodiments.

FIG. 2A is a diagram that depicts operations that controller may perform to identify a degraded or faulty battery cell of a battery stack according to some embodiments.

FIG. 2B is a diagram that depicts operations a controller may perform to determine derivatives Z_{BATT} of a plurality of N battery cells as an approximation of impedance according to some embodiments.

FIG. 3 is a graph showing a non-limiting example of a shared current of a battery stack over time according to some embodiments.

FIG. 4A is a block diagram that shows one example of a controller operated to arrange cells of a battery stack into subsets according to some embodiments.

FIG. 4B depicts a graph that plots the comparison of metrics across the subsets depicted in FIG. 4A.

FIG. 5 is a diagram that depicts one example of operations controller may perform to identify a degraded or faulty battery cell of a battery stack according to some embodiments.

FIG. 6A depicts one example of a battery stack that includes twenty battery cells arranged in subsets according to some embodiments.

FIG. 6B depicts another example of a battery stack that includes twenty battery cells arranged in subsets with similarly situated battery cells according to some embodiments.

FIG. 7 is a flow chart that depicts one example of a method of operating a battery controller according to some embodiments.

### DETAILED DESCRIPTION

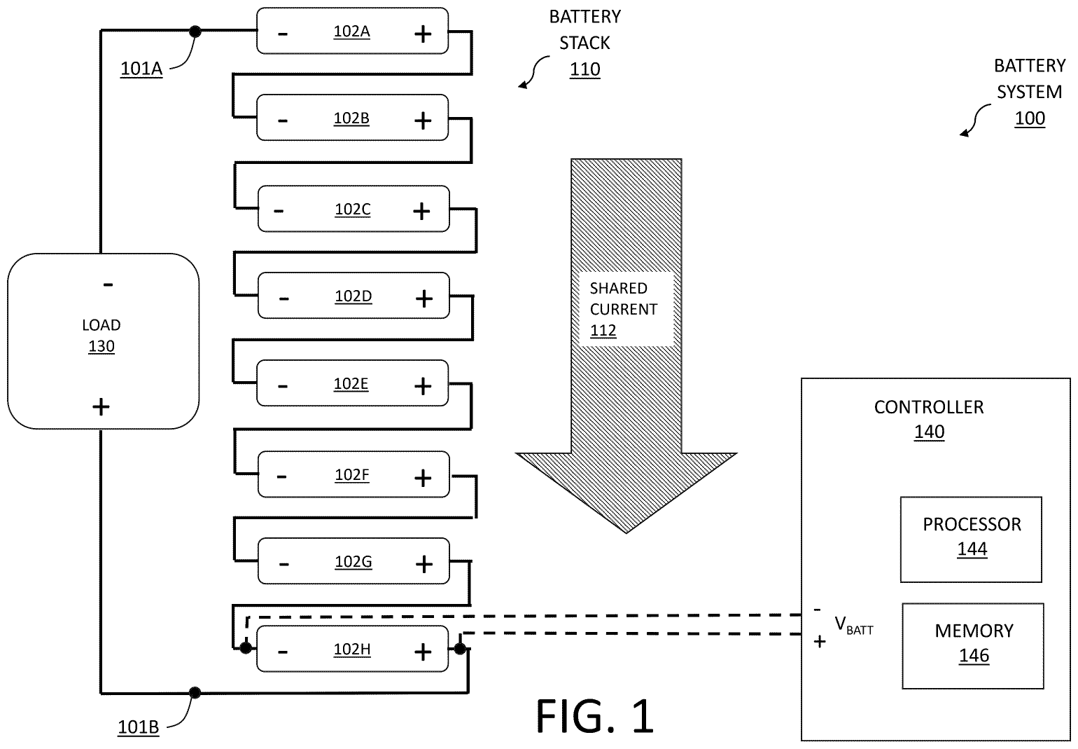

FIG. 1 is a block diagram that depicts one example of a battery system 100 according to some embodiments. As shown in FIG. 1, the battery system 100 includes a battery stack 110 that including a plurality of battery cells 102A-102H (collectively “battery cells” 102) that are coupled to in series across terminals 101A, 101B of the battery system 100 that are coupled to supply energy to a load 130. Coupled in series as shown, a shared current 112 runs through the battery cells 102A-102H of the battery stack 110.

As shown in FIG. 1, battery system 100 further includes a controller 140. Controller 140 may be a processing component such as a microprocessor coupled to control each battery cell 102 of the battery stack 110, for example to couple or decouple each respective battery cell 102 from terminals 101A, 101B. Controller 140 may monitor cell voltages across each battery cell 102. The example of FIG. 1 shows controller 140 coupled to respective positive and negative terminals of a battery cell 102H, to measure a battery voltage V_{BATT} across the battery cell 102H. In other examples not depicted, controller 140 is coupled to each of the plurality of N battery cells 102A-102H and configured to control each battery cell 102 and to measure or receive measurements of a battery voltage V_{BATT} associated with each battery cell 102. For example, controller 140 and/or other components of battery system 100 not depicted include an Analog to Digital Converter (ADC) configured to convert a measured analog voltage across each battery cell 102 and generate a digital bit stream that represents the measured analog voltages for use by the controller 140.

As also shown in FIG. 1, terminals 101A, 101B may be coupled to a load 130 to supply energy to the load 130. The load 130 may be an electric motor of a small handheld device such as a power tool. As another non-limiting example, the load 130 may be an electric motor of a Battery Electric Vehicle (BEV) such as an electric or hybrid vehicle. According to still other examples, load 130 may include another battery, or any other type of load 130 configured to be powered by battery cells 102 of a battery stack 110.

The controller 140 is arranged to control power switches (not shown in FIG. 1) coupled across each battery cell 102 to decouple or couple the respective battery cell 102 to the terminals 101A, 101B to supply energy to the load 130. As one non-limiting example where the load 130 is a power tool, the controller 140 couples at least some of battery cells 102A-102H to the load 130 in response to an operator actuating a trigger of the power tool, and decouples at least some of the battery cells 102A-102H from the electric motor when the trigger is released. According to another example, where the load 130 is an electric motor of a BEV, the controller 140 may couple at least some of the battery cells 102A-102H to the load 130 in response to a human or autonomous vehicle operator actuating a drive system (e.g., a gas pedal or the autonomous equivalent) of the vehicle, and decouple at least some of the battery cells 102A-102H from the load 130 in response to an operator de-actuating the drive system (e.g., releasing the gas pedal, applying the brake pedal, or the autonomous equivalents).

According to traditional battery systems, a controller may operate to monitor cells of a battery stack, for example to detect degraded or faulty cells of a battery stack. According to such traditional systems, the controller regularly injects a current with a known magnitude, and measures cell voltages of each cell in response to the injected current as an impedance of each cell, which can be accurately calculated because the magnitude of the injected current is known. In some examples, such a current may have a magnitude of at least two amperes, which may expend a significant amount of energy each time the impedance of the battery cells are measured, which may be quite frequently in some applications.

In some examples, such as where load 130 comprises an electric motor of a BEV, a battery stack 110 depicted in FIG. 1 may include hundreds, or even thousands of battery cells 102. As one non-limiting example, a battery system 100 may be configured to power a motor of a BEV as load 130 to supply energy at voltage levels up to 800 volts. According to one such example, battery system 100 may a battery stack 110 include 200 battery cells 102 that are each configured to supply and store energy in a range of about 3.8-4.2 volts.

Controller 140 depicted in FIG. 1 may be uniquely configured to detect degraded and/or faulty battery cells of a battery stack 110, without the injection of a known current to determine an impedance of each battery cell. For example, controller 140 may measure battery voltages V_{BATT} across each battery cell 102 and use the measured battery voltages V_{BATT} to identify one or more degraded or faulty battery cells.

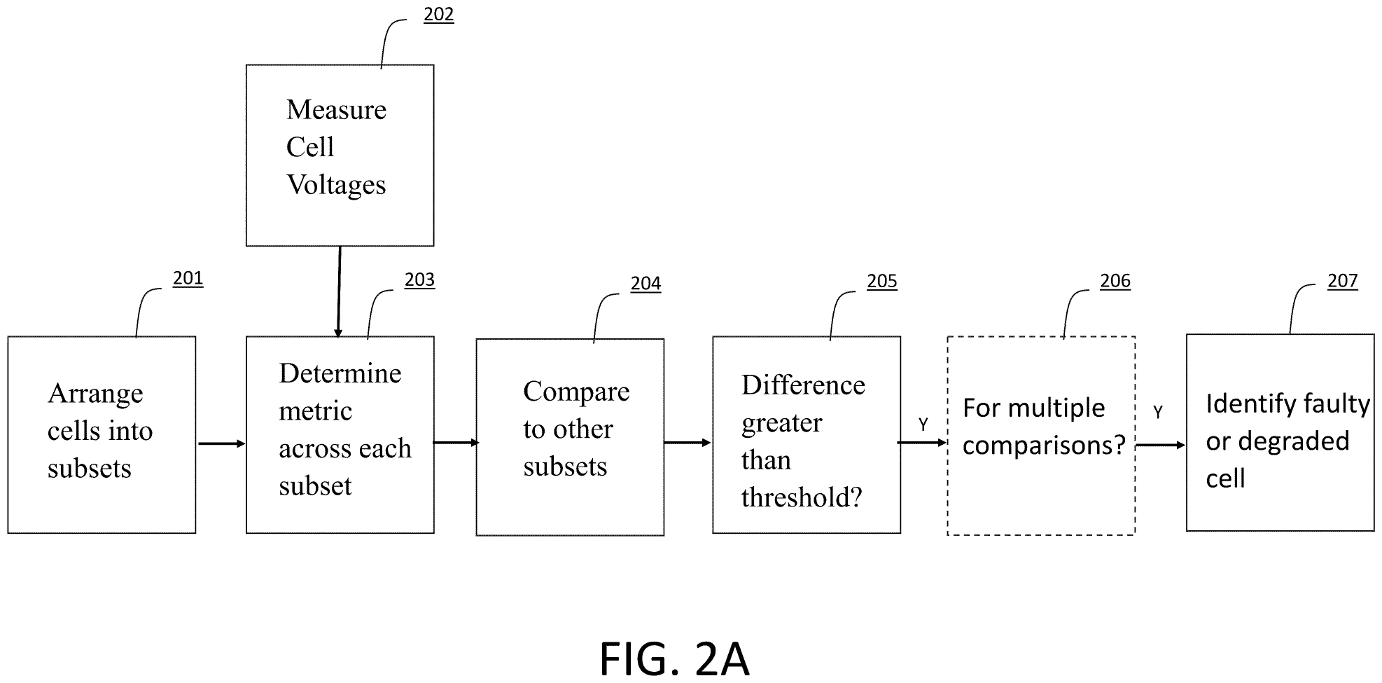

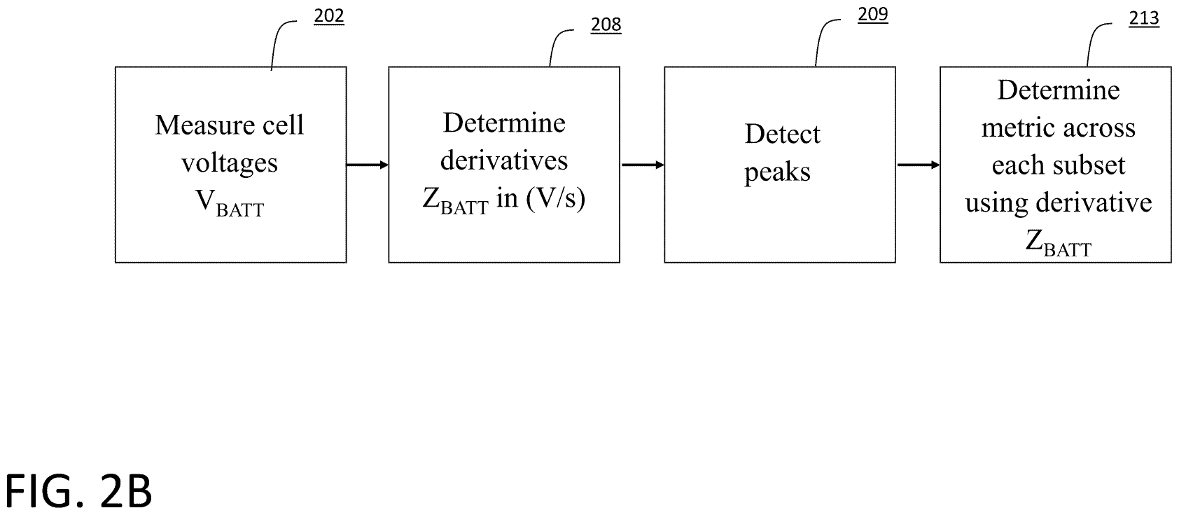

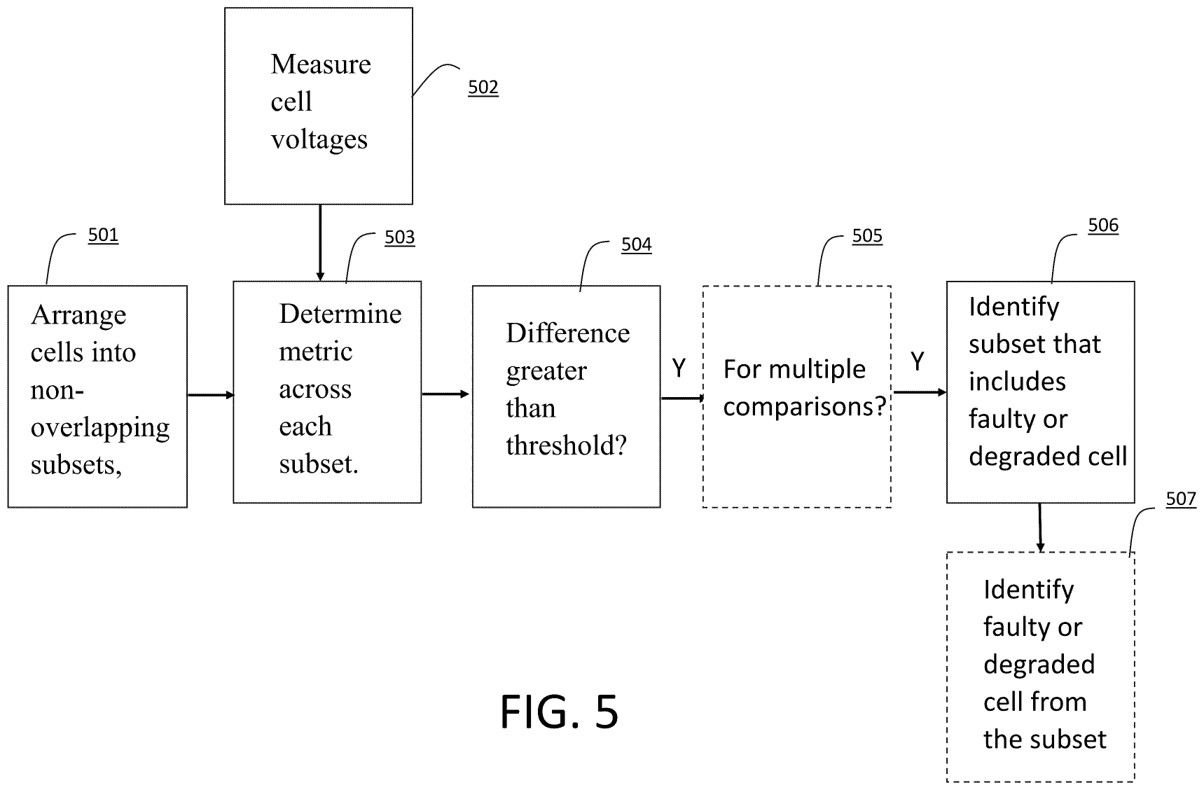

As shown in FIG. 1, controller 140 includes a processor 144 and a memory 146. Below, various operations that may be performed by controller 140 are described, for example with respect to the flow diagrams depicted in FIGS. 2A, 2B, and 5. One of ordinary skill in the art will understand the each of these operations may be implemented in any manner, for example by dedicated circuitry, programmable firmware, or the like. In other examples, the various functions performed by controller 140 may be implemented by software instructions stored in memory 146, which may be described as a non-transitory computer-readable medium, that are executable by the processor 144 to cause the controller 140 to operate as described.

FIG. 2A is a diagram that depicts operations that controller 140 may perform to identify a degraded or faulty battery cell 102 of a battery stack 110 according to some embodiments. As shown in FIG. 2A, at 201, the controller 140 arranges a plurality of N battery cells 102A-102H into subsets. The subsets are groupings of 2-M cells, with M being a number less than N. For example, the subsets may be groupings of two or three battery cells, or may include even more battery cells, for example 4-10 or even 20 battery cells.

As shown in FIG. 2A, at 202, the controller 140 measures cell voltages V_{BATT} across each battery cell 102A-102H. In some examples, the controller 140 measures the cell voltages as a moving average across a sampling window. As a specific non-limiting example, the controller 140 measures the cell voltages V_{BATT} during a sampling window of 5-20 milliseconds.

As also shown in FIG. 2A, at 203, the controller 140 determines at least one metric across each subset, to be used at 204 for comparison. The at least one metric is a value across the battery cells of each subset. The controller 140 determines the at least one metric across each subset using the measured cell voltages V_{BATT}.

For example, the controller 140 may determine a metric that includes a mean (average) voltage V_{MEAN} across the M battery cells of each subset, which represents the summations of the measured battery cell voltages V_{BATT} of the M cells divided by the number of M battery cells of the subset during the sampling window. According to another example, the controller 140 determines a metric that includes a median voltage V_{MEDIAN} across each subset, which represents a set of measured voltages V_{BATT} in a middle of a distribution arranged from largest to smallest (or smallest to largest) of the subset during the sampling window. According to another example, the controller 140 determines a metric that includes a mode voltage V_{MODE} across each subset, which represents a measured voltage that occurs most often across the M battery cells of the subset during the sampling window. As another example, the controller 140 determines a metric that includes a maximum voltage V_{MAX} across the M battery cells of each subset, which represents a maximum of the voltage V_{BATT} across the M battery cells of each subset during the sampling window. As another example, the controller 140 determines a metric that includes a minimum voltage V_{MIN} across the M battery cells of each subset, which represents a minimum of the voltages V_{BATT} across the M battery cells of a subset during the sampling window. According to another example, the controller 140 determines a metric that includes a difference V_{DIFF} across the battery cells of each subset, which represents difference between measured voltages V_{BATT} across the battery cells of each subset during the sampling window. According to another example, the controller 140 determines a metric that includes a standard deviation V_{STD} across the battery cells of each subset, which represents an average difference between measured voltages V_{BATT} across the battery cells of each subset relative to one another during the sampling window.

Referring again to FIG. 2A, at 203, controller 140 determines at least one metric (e.g, one or more of V_{MEAN}, V_{MEDIAN}, V_{MODE}, V_{MAX}, V_{MIN}, V_{DIFF}, and/or V_{STD}) across each subset as described above. At 204, the controller 140 compares the metrics across each subset to metrics across each other subset to identify degraded or faulty battery cell(s). In some examples, as shown in FIG. 2B, the controller 140 processes the measured battery voltages V_{BATT} to determine derivatives Z_{BATT} as an approximation of impedance, and uses the derivatives Z_{BATT} to determine metrics associated with each subset.

FIG. 2B is a diagram that depicts operations a controller 140 may perform to determine derivatives Z_{BATT} of a plurality of N battery cells as an approximation of impedance according to some embodiments. As shown in FIG. 2B, at 202, the controller 140 measures cell voltages V_{BATT} as described above with respect to FIG. 2A, for example during a sampling window as a moving average. At 208, the controller 140 determines derivatives Z_{BATT} of the cell voltages V_{BATT} by calculating the derivative of the cell voltages V_{BATT} over time, for example during a sampling window. In some examples, the controller 140 uses the determined derivatives Z_{BATT} to determine metrics.

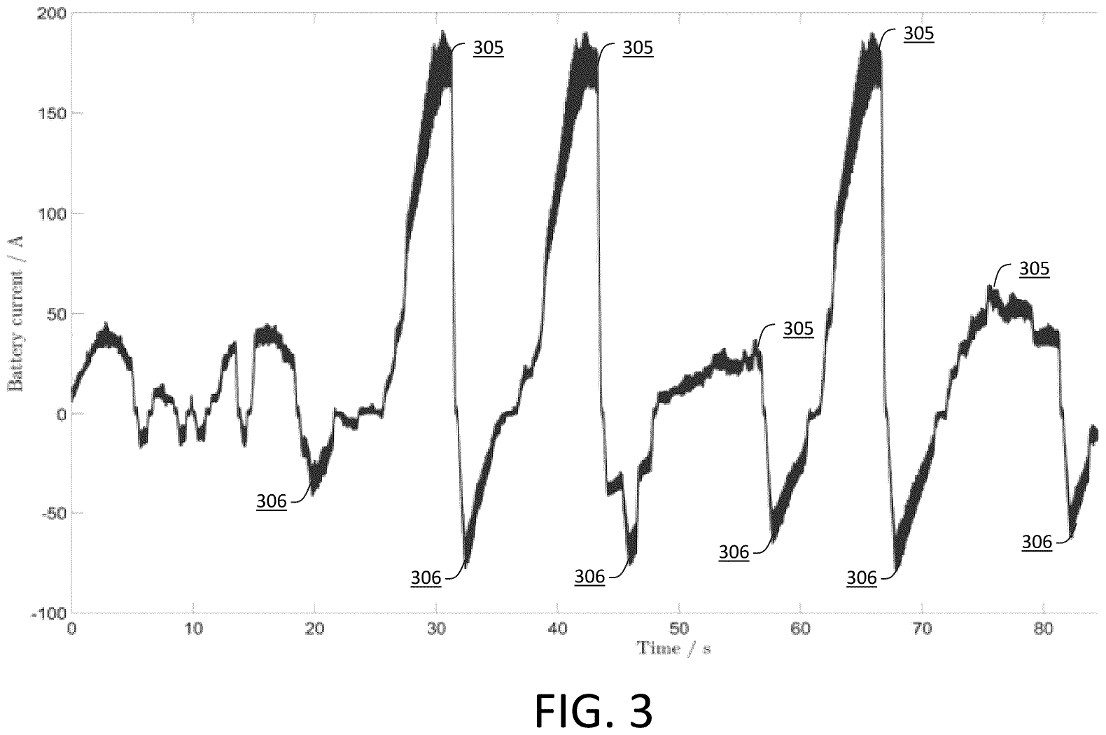

In some examples, as shown at 209 in FIG. 2B, the controller 140 determines the metrics across each subset based on using measurements taken during times that correspond to peaks in the shared current 112, which correspond to actuation and/or recuperation of a load 130, as shown in the example of FIG. 3.

FIG. 3 is a graph showing a non-limiting example of a shared current 112 of a battery stack 110, as shown in the example of FIG. 1 over time as the battery stack 110 is controlled to deliver energy to motor of a BEV as a load 130 according to some embodiments. As shown in FIG. 3, when battery system 100 is operated to supply energy to load 130, a current 112 through the battery stack 110 varies between positive peaks 305, and negative peaks 306 that correspond to actuation and/or recuperation of the load 130. As also shown in FIG. 3, the actuation and/or recuperation of the load 130 imparts noise on the shared current 112 signal around the peaks 305, 306.

Referring back to FIG. 2B, at 209, the controller 140 uses the derivatives Z_{BATT} to identify peaks 305, 306 in the shared current 112. At 213, the controller 140 determines metric(s) across subsets using the derivatives Z_{BATT}. In some examples, the controller 140 determines the derivatives Z_{BATT} based on battery voltage V_{BATT} measurements taken during times (e.g., during a sampling window) that correspond to the identified peaks 305, 306, during which a strong but unknown current flows through the battery stack 110.

For example, to identify peaks 305, 306, the controller 140 may monitor the derivatives Z_{BATT} to identify when the derivative Z_{BATT}=0, which may indicate that a slope of the battery cell voltages V_{BATT} has changed from positive to negative or negative to positive.

In other examples, the controller 140 may not monitor the derivatives Z_{BATT} to identify peaks 305, 306. According to these examples, controller 140 monitors the battery voltages V_{BATT} for a frequency of expected noise associated with actuation or recuperation of load 130 to identify the peaks 305, 306.

As shown at 213 in FIG. 2B, regardless of how the peaks 305, 306 are identified, the controller 140 uses the determined derivatives Z_{BATT} surrounding the peak (e.g., derivatives Z_{BATT} based battery voltages V_{BATT} sampled during a sampling window centered at or near the peak) to determine metric(s) across each subset. In some examples, using the derivatives Z_{BATT} based on measured battery voltages V_{BATT} associated with peaks 305, 306 may serve as a more accurate reflection of battery cell 102 condition than using the measured battery voltage V_{BATT} to determine metrics across subsets, as described above. In some examples, using the derivatives Z_{BATT} based on measured battery voltages V_{BATT} associated with peaks 305, 306 may enable early identification of battery cell 102 condition in comparison to using the measured battery voltage V_{BATT} to determine metrics across subsets, as described above.

Referring back to FIG. 2A, at 203, the controller 140 determines at least one metric across each subset, to be used at 204 for comparison. As shown in FIG. 2B at 213, in some embodiments, the controller 140 determines the metric(s) across each subset using the derivatives Z_{BATT}, which may be determined using cell voltages V_{BATT} measured during a sampling window that corresponds to a peak 305, 306 in the shared current 112 in some embodiments.

For example, the controller 140 may determine a metric that includes a mean (average) impedance Z_{MEAN} across the M battery cells of each subset, which represents the summations of the measured derivatives Z_{BATT} of the M cells divided by the number of M cells during a sampling window. According to another example, the controller 140 determines a metric that includes a median impedance Z_{MEDIAN} across each subset, which represents a set of determined impedances Z_{BATT} in a middle according to a distribution arranged from largest to smallest (or smallest to largest) during the sampling window. According to another example, the controller 140 determines a metric that includes a mode impedance Z_{MODE} across each subset, which represents an impedance that occurs most often across the M battery cells of each subset during the sampling period. As another example, the controller 140 determines a metric that includes a maximum impedance Z_{MAX} across the M battery cells of each subset during the sampling window. As another example, the controller 140 determines a metric that includes a minimum impedance Z_{MIN} across the M battery cells of each subset which represents a minimum of the derivatives across the M battery cells during the sampling window. According to another example, the controller 140 determines a metric that includes an impedance difference Z_{DIFF} across the battery cells of each subset, which represents a difference between impedances Z_{BATT} across the battery cells of each subset during the sampling window. According to another example, the controller 140 determines a metric that includes a standard deviation Z_{STD} across the battery cells of each subset, which may represent an average difference between impedances Z_{BATT} across the M battery cells of each subset relative to one another.

Referring back to FIG. 2A, when the controller 140 has determined the metric across each battery cell at 203, which may be based on measured battery voltages V_{BATT}(e.g., one or more of V_{MEAN}, V_{MEDIAN}, V_{MODE}, V_{MAX}, V_{MIN}, V_{DIFF}, and/or V_{STD}), and/or at 213 based on determined derivatives Z_{BATT} (e.g., one or more of Z_{MEAN}, Z_{MEDIAN}, Z_{MODE}, Z_{MAX}, Z_{MIN}, Z_{DIFF}, and/or Z_{STD}), the controller 140 compares the determined metrics for each subset to one another at 204.

At 205, if the metrics differ from one another by more than a predetermined threshold, at 207, the controller 140 identifies a subset as including a degraded or faulty cell. As an optional embodiment, at 206, if the controller 140 determines that the comparison of multiple subset metrics that include a battery cell in common differ from other subset metrics that don't include the battery cell by more than a difference threshold, the controller 140 identifies the battery cell as a degraded or faulty at 207.

In some examples, the controller 140 sequentially measures and calculates characteristics of the battery cells 102 such as the cell voltages V_{BATT}, the optionally determined derivatives Z_{BATT}, metrics, and/or the results of comparisons between the metrics in memory as controller 140 operates to control battery system 100 to supply energy to a load 130. According to some examples, the controller 140 may track and/or predict changes in the battery cell characteristics over time as controller 140 operates to control battery system 100 to supply energy to a load 130. According to one such example, the controller 140 may compare metrics and/or comparisons associated with different detected peaks 305, 306 in shared current 112 to one another over time as an indication of battery cell health, i.e., whether one or more battery cells include a faulty or degraded battery cell.

Once a degraded or faulty cell is identified, the controller 140 may take one or more steps to mitigate an impact of the degraded or faulty cell. For example, the controller 140 may trigger a notification to a vehicle operator, vehicle manufacturer or distributor, a repair specialist, or other party that the battery stack 110 is not functioning properly, for example to trigger repair or replacement of the battery stack 110 or the identified cell. In other examples, the controller 140 modifies control of the battery system 100 to accommodate for the degraded or faulty battery cell. For example, the controller 140 may cease to actuate the degraded or faulty cell, for example by using other battery cells of the battery stack 110 to supply energy to a load 130.

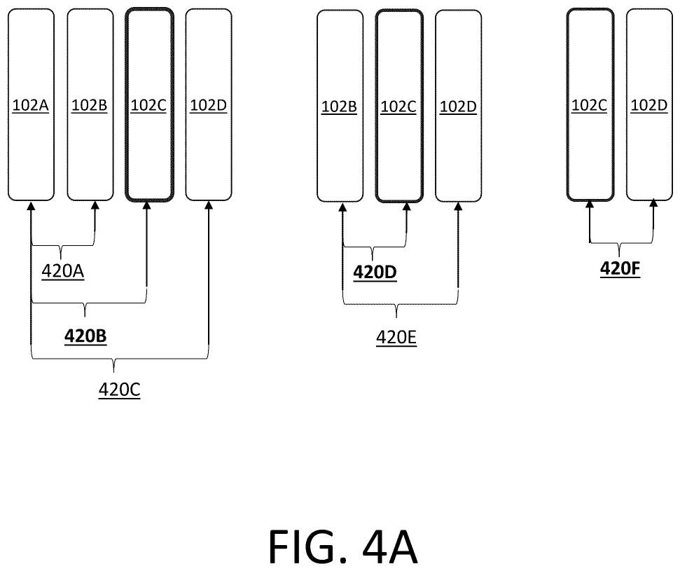

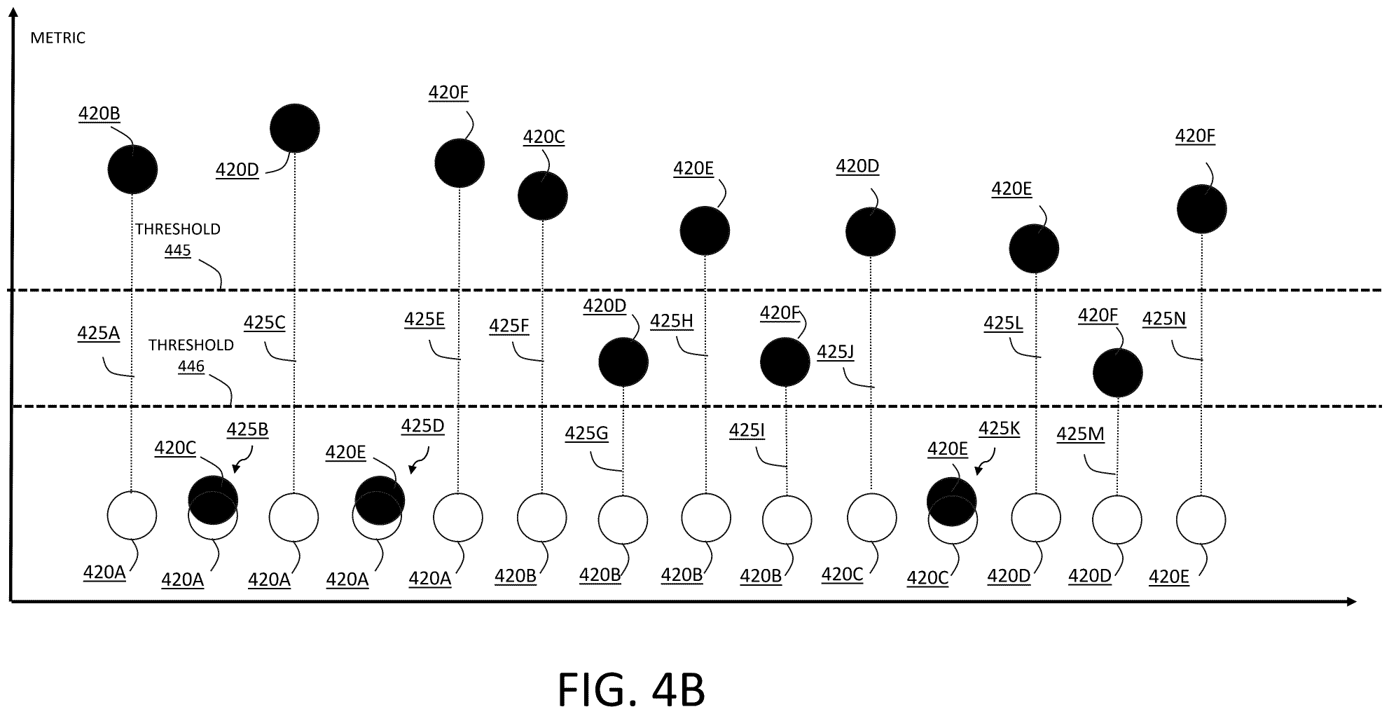

FIG. 4A is a block diagram that shows one example of a controller 140 operated to arrange battery cells 102A-102D of a battery stack 110 into subsets 420A-420F according to some embodiments. According to the example of FIG. 4A, a battery stack 110 includes four cells 102A-102D, each of which are coupled in series to one another as shown in the FIG. 1 example. In other examples not depicted, battery stack 110 may include many more than just four cells. For example, in some applications, battery stack 110 may include up to a hundred, hundreds, or even thousands of battery cells 102.

According to the example of FIG. 4A, the controller 140 operates to arrange the battery cells 102A-102D into subsets 420A-420F that represent each possible combination of battery cells 102A-102D in pairs. For example, as shown in FIG. 4A, the controller 140 arranges battery cells 102A and 102B in a subset 420A, battery cells 102A and 102C in a subset 420B, battery cells 102A and 102D in a subset 420C, battery cells 102B and 102C in a subset 420D, battery cells 102B and 102D in a subset 420E, and battery cells 102C and 102D in a subset 420F.

According to the example of FIG. 4A, the controller 140 arranges the cells 102A-102E into subsets 420A-420F that each include a pair of two cells. In other examples, the battery stack 110 may include far more than four battery cells 102A-102E, for example including tens or hundreds of battery cells, and the controller 140 similarly arranges the hundreds of cells into subsets representing each possible pair of the tens or hundreds of subsets. According other examples, the controller 140 arranges the battery cells of a battery stack 110 into larger subsets, for example with 3, 4, or even more cells per subset that represent each unique combinations of 3, 4 or even more battery cells 102A-102E of the battery stack 110.

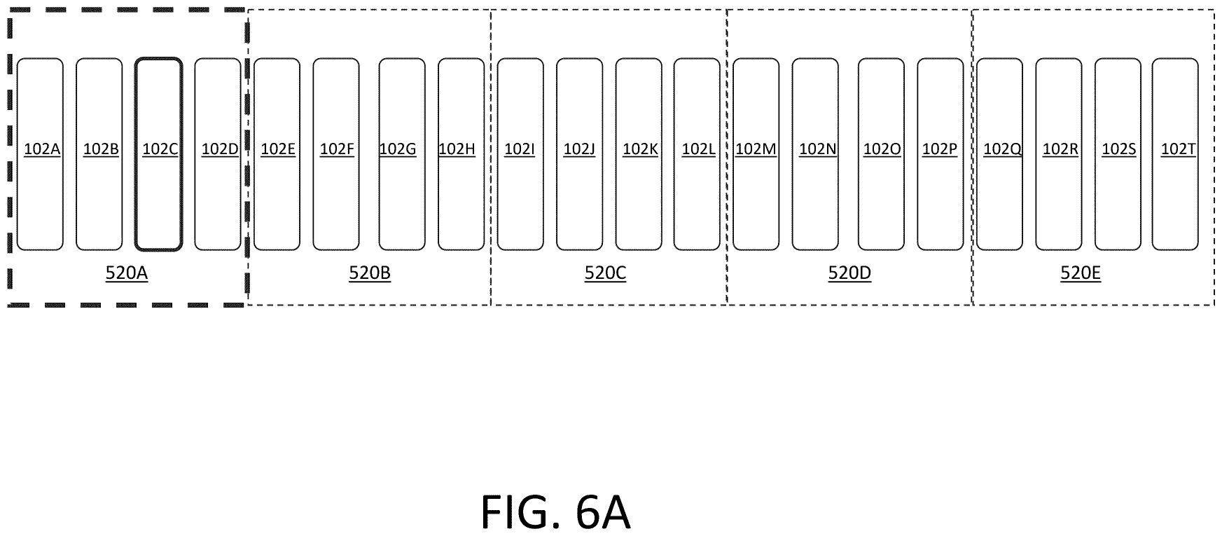

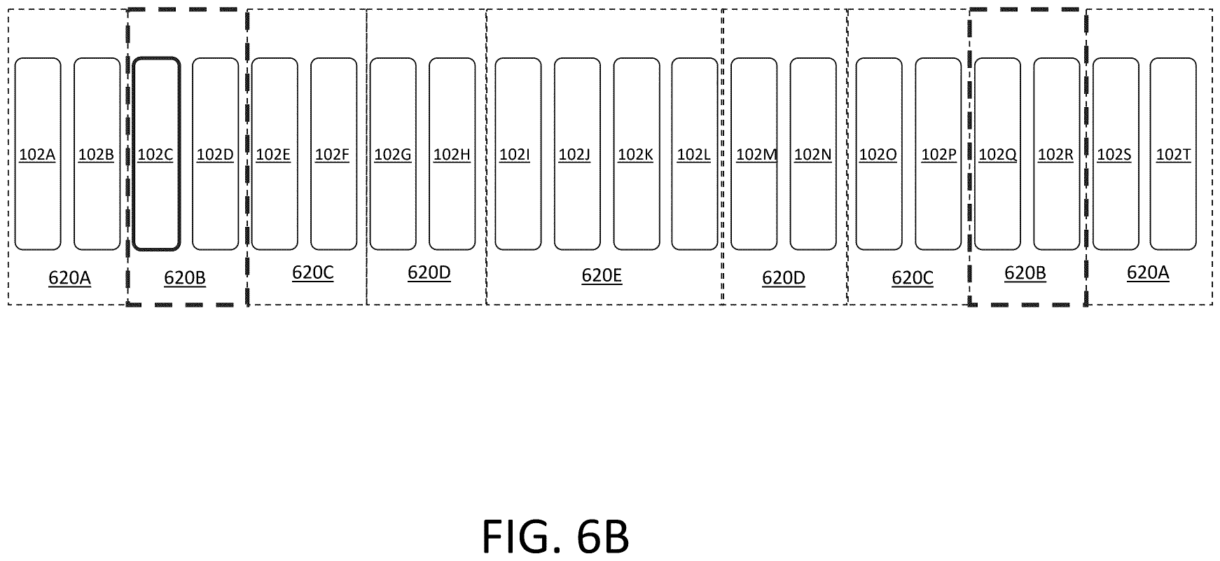

According to the example of FIG. 4A, the respective subsets 420A-420F include cells 102A-102D that are also included in other subsets, which are referred to as “overlapping subsets” 420A-420F herein. In other examples, the controller 140 instead, or in addition, arranges cells of a battery stack 110 into “non-overlapping” subsets that do not include battery cells of other subsets, as further described below with respect to the examples of FIGS. 6A and 6B.

FIG. 4B depicts a graph that plots comparisons 425A-425N of metrics across the subsets 420A-420F depicted in FIG. 4A. In the example of FIG. 4B, the vertical y-axis of the chart represents a relative magnitude, or difference between, metrics across subsets 420A-420F for a plurality of comparisons 425A-425N across the horizontal x-axis. The metric(s) compared in the FIG. 4B chart may be based on measurements across battery cells of each subset 420A-420F and may be based on measured battery voltages V_{BATT}(e.g., one or more of V_{MEAN}, V_{MEDIAN}, V_{MODE}, V_{MAX}, V_{MIN}, V_{DIFF}, and/or V_{STD}), and or determined derivatives Z_{BATT} (e.g., one or more of Z_{MEAN}, Z_{MEDIAN}, Z_{MODE}, Z_{MAX}, Z_{MIN}, Z_{DIFF}, and/or Z_{STD}) as an approximation of impedance as described above.

As shown in FIG. 4B, according to comparisons 425B, 425D, and 425K the metrics of subsets 420A, 420C, and 420E differ only slightly when compared to one another, by an amount that is less than the difference threshold 445. In contrast, according to the comparisons 425A, 425C, 425E, 425F, 425H, 425J, 425L, and 425N, the metrics across subsets 420B, 420D, and 420F differ significantly when compared to metrics across subsets 420A, 420C, and 420E, by an amount greater than the difference threshold 445. According to this example, the controller 140 may identify a degraded or faulty cell based on the comparisons 425A-425N shown in FIG. 4B. For example, since comparisons 425B, 425D, and 425K are below the threshold 445 (and/or the threshold 446) the controller 140 may determine that the subsets 420A, 420C, and 420E are “healthy” subsets, and that battery cells 102A, 102B, and 102D are not degraded or faulty. As another example, since comparisons 425A, 425C, 425E, 425F, 425H, 425J, 425L, and 425N indicate a difference between metrics that exceed the threshold 446, the controller may determine that subsets 420B, 420D, and 420F are “unhealthy” subsets that include at least one unhealthy cell. Since the subsets 420B, 420D, and 420F all share battery cell 102C in common, the controller 140 may identify battery cell 102C as degraded or faulty.

In some examples, as shown in FIG. 4B, when the controller 140 compares metrics across the subsets 420B, 420D, and 420F to one another, the metrics differ from one another more than the “healthy” subsets 420A, 420C, and 420E differ, but less than when compared to the “healthy” subsets 420A, 420C, and 420E. As shown in FIG. 4B, comparisons 425G, 425I, and 425M represent metric comparisons of the “unhealthy” subsets 420B, 420D, and 420F to one another.

In some examples, the controller 140 may further use the comparisons of metrics of “unhealthy” subsets 420B, 420D, and 420F to one another as a further indication that a battery cell is degraded or faulty. For example, the controller 140 may implement a second difference threshold 446 as shown in FIG. 4B, and identify a degraded or faulty cell based on metric comparisons 425G, 425I, and 425M that differ by an amount less than the first difference threshold 445 but more than the second difference threshold 446.

Referring back to FIG. 2A, in some examples, the controller 140 may identify a battery cell as degraded or faulty when a single one of comparisons 425A-425N shows a difference between metrics that exceeds one or more of the difference thresholds 445, 446. In other examples, the controller 140 may identify a battery cell as degraded or faulty when multiple comparisons 425A-425N indicate a degraded or faulty battery cell. For example, in the example of FIG. 4B, the controller 140 may be configured to count a number of comparisons 425A, 425C, 425E, 425F, 425H, 425J, 425L, and 425N that indicate a difference between metrics that exceeds the thresholds 445 and/or 446, and identify a degraded or faulty cells only when a predetermined number of comparisons exceed the threshold. For example, the predetermined number may be expressed as a ratio or percentage of the subset comparisons 425A-425N.

As mentioned above, in the example of FIGS. 4A and 4B, the controller 140 arranges battery cells 102 of a battery stack 110 that includes only four cells 102A-102D arranged into six subsets 420A-420F, and performs 14 comparisons 425A-425N between metrics across each subset 420A-420F to identify a degraded or faulty cell based on a difference between subsets 420A, 420C, and 420E that include healthy battery cells 102A, 102B, and 102D, and subsets 420B, 420D, and 420F, which include the degraded or faulty battery cell 102C in common. The example of FIGS. 4A and 4B is intentionally simplified for purposes of explanation. In some applications, the described techniques may be applied by a controller 140 to a battery stack 110 with any number of N battery cells. For example, the controller 140 may arrange five battery cells of a battery stack 110 in 10 unique subsets and perform 45 comparisons between the metrics across each subset to identify degraded or faulty cells. According to another example, the controller 140 may arrange a hundred battery cells of a battery stack 110 into 4,950 unique subsets, and perform 12,248,775 comparisons between the metrics across each subset to identify degraded or faulty cells.

According to the simplified example of FIGS. 4A and 4B, one of the four battery cells is degraded or faulty, and the controller 140 arranges the battery cells 102A-102D into six subsets, half of which include the degraded or faulty cell 102C, resulting in a small proportions of (three of fourteen) “healthy” metric comparisons 425B, 425D, and 425K. According to this example, the three “healthy” metric comparisons 425B, 425D, and 425K are used as a baseline to differentiate ten “unhealthy” metric comparisons that indicate subsets 420B, 420D, and 420F include a degraded or faulty cell (e.g., that represent a difference greater than the difference thresholds 445 and/or 446). However, when battery stack 110 includes a greater ratio of presumably “healthy” subsets, the comparison of the many “healthy” subsets to one another may serve as a more reliable baseline to identify degraded or faulty cell(s).

As mentioned above, in some examples, battery stack 110 may include many tens, or even hundreds, of battery cells, which may require a significant amount of computational power to compare the metrics across each subset to one another. In some examples, instead of arranging the battery cells into subsets as pairs, the controller 140 arranges the battery cells into subsets that include unique combinations of three, four, or even more battery cells. In some examples, by using larger subsets, the controller 140 may reduce a number of metric comparisons performed to identify degraded or faulty cells and therefore a computational complexity to identify degraded or faulty battery cells.

As mentioned above, in order to determine with confidence that battery cells of a battery stack 110 are degraded or faulty, the controller 140 uses “healthy” comparisons between metrics across subsets that do not include any degraded or faulty battery cells as a baseline. In some examples, if controller 140 determines that there are an insufficient number, or proportion, of “healthy” subset comparisons, the controller 140 may determine that battery stack 110 is no longer suitable to serve as a power source for a particular application. According to one such example, if the controller 140 determines that less than a threshold percentage (e.g., less than 60, 70, 80, 90, 95 percent) of subset metric comparisons indicate “healthy” subsets suitable to use as a baseline, the controller 140 creates a notification, alarm, or alert that the battery stack 110 is to be replaced or repaired.

In some examples, battery system 100, which includes a controller 140 operable to identify degraded or faulty cells of a battery stack based on measuring cell voltages, may consume less energy than traditional battery controllers that inject a known current to directly measure impedance.

In some examples, a battery system 100 includes controller 140 that is only configured to use measured cell voltages to identify degraded or faulty battery cells, i.e., the controller 140 does not include circuitry and/or executable software configured to inject a known current through the battery cells to measure an impedance of each battery cell as an indication of battery cell condition.

In other examples, the controller 140 is operable to use both measured cell voltages and traditional techniques to effectively identify degraded or faulty cells while operating with reduced energy usage. For example, controller 140 may frequently perform the operations described with respect to FIGS. 2A and/or 2B above (e.g., during operation the battery system 100 to supply energy to a load 130), and less frequently (e.g., upon start up, shut down, etc.) inject a known current to directly measure battery cell impedances as a more accurate indication of battery cell condition.

In still other examples, the controller 140 may regularly use measured cell voltages V_{BATT} of battery cells arranged into subsets to identify degraded or faulty battery cells, and once the controller 140 has identified one or more battery cells suspected to be degraded or faulty, inject a known current and perform measurements to verify that the battery cell(s) are faulty and/or degraded using traditional techniques. According to each of these examples, controller 140 may operate with reduced power consumption in comparison to traditional battery controllers that inject a known current to identify degraded or faulty battery cells each time the battery cells are monitored and therefore consume a significant amount of extra energy to monitor the condition of battery cells of a battery stack 110.

FIG. 5 is a diagram that depicts one example of operations that controller 140 may perform to identify a degraded or faulty battery cell 102A-102H of a battery stack 110 according to some embodiments. As shown in FIG. 2A, at 201, the controller 140 arranges a plurality of N battery cells 102A-102H into subsets that are groupings of 2-M cells, with M being a number less than N. At 501, the example of FIG. 5 differs from the example of FIG. 2A in that the controller 140 arranges cells 102A-102H of a battery stack 110 into non-overlapping subsets. According to these examples, the non-overlapping subsets each include a number N of battery cells, but each subset does not include battery cells of other subsets.

FIG. 6A depicts one example of a battery stack 110 that includes 20 battery cells 102A-102T arranged in subsets according to some embodiments. According to FIG. 6A, the controller 140 arranges the cells 102A-102T into subsets 520A-520E, which each include four adjacent cells. According to the example of FIG. 6A, subset 520A includes cells 102A-102D, subset 520B includes cells 102E-102H, subset 520C includes cells 102I-102L, subset 520D includes cells 102M-102P, and subset 520E includes cells 102Q-102T. As shown in the FIG. 6A example, the subsets are non-overlapping, i.e. none of the subsets 520A-520E includes the same cell 102A-102T.

FIG. 6B depicts another example of a battery stack 110 that includes 20 battery cells 102A-102T arranged in subsets according to some embodiments. FIG. 6B depicts controller 140 has arranged the battery cells 102A-102T into subsets 620A-620E in which similarly situated cells are arranged in each subset 620A-620E. As shown in FIG. 6B, the controller 140 has arranged the cells 102A-102T into subsets 620A-620E that each include four cells, some of which are non-adjacent. According to the example of FIG. 6B, the battery cells 102A-102T are arranged subsets 620A-620E based on a relative position in a battery stack 110, grouping cells together that may experience external and/or environmental influences together in the battery stack 110. According to the example of FIG. 6B, the controller 140 has arranged cells 102A and 102B and cells 102S and 102T in a subset 620A that correspond to the respective ends of the battery stack 110. The controller 140 has arranged cells 102C and 102D and cells 102Q and 102R in a subset 620B adjacent to subset 620A. The controller 140 has arranged cells 102E and 102F and cells 102O and 102P in a subset 620C adjacent to subset 620B. The controller 140 has arranged cells 102G and 102H and cells 102M and 102N in a subset 620D adjacent to subset 620C. The controller 140 has also arranged cells 102I-102L in a subset 620E, which corresponds to a middle section of the battery stack 110 furthest away from the ends of the battery stack 110, adjacent to the subset 620D.

Referring back to FIG. 5, whether the battery cells 102A-102T are arranged into subsets 520A-520E depicted in FIG. 6A, or the subsets 620A-620E depicted in FIG. 6B, at 502 the controller 140 measures cell voltages of the battery cells 102A-102T. At 503, the controller 140 determines a metric across each of the subsets 520A-520E, 620A-620E. At 504, the controller 140 compares the metrics of each subset 520A-520E, 620A-620E to one another. As described above with respect to FIG. 2A, the metric across each of the subsets may be based on a measured battery voltages V_{BATT} (e.g., one or more of V_{MEAN}, V_{MEDIAN}, V_{MODE}, V_{MAX}, V_{MIN}, V_{DIFF}, and/or V_{STD}), and or determined derivatives Z_{BATT} (e.g., one or more of Z_{MEAN}, Z_{MEDIAN}, Z_{MODE}, Z_{MAX}, Z_{MIN}, Z_{DIFF}, and/or Z_{STD}) of the measured battery voltages. In some examples, as described above with respect to FIGS. 2B and 3, the metrics may be determined based on measurements (e.g., of the battery voltages V_{BATT}) taken during detected peaks 305, 306 in the shared current 112.

At 504, if a difference between the metrics is greater than a difference threshold, the controller 140 determines that a subset 520A-520E, 620A-620E includes a degraded or faulty cell at 506. In optional embodiments, at 505, the controller 140 may determine that a subset 520A-520E, 620A-620E includes a degraded or faulty cell when multiple comparisons of a subset metric to other subset metrics indicate a difference greater than the threshold.

Once the controller 140 determines that a subset 520A-520E, 620A-620E includes a degraded or faulty cell (an “unhealthy” subset), in some examples the controller 140 initiates a response to mitigate the degraded or faulty cell. For example, the controller 140 may trigger a notification to a vehicle operator, manufacturer or distributor, repair specialist, or other party that the “unhealthy” subset/battery stack 110 is not functioning properly, for example to trigger repair or replacement of the battery stack 110 or the battery cells of the identified “unhealthy” subset. In other examples, the controller 140 modifies operation of battery system 100 to accommodate for the degraded or faulty battery cell. For example, the controller 140 may cease to actuate the battery cells of the identified “unhealthy” subset, for example by using other cells of the battery stack 110 to supply energy to a load 130.

In other examples, at 507 the controller 140 optionally performs further operations to identify which battery cell of an identified “unhealthy” subset is degraded or faulty. According to these examples, the non-overlapping subsets 520A-520E, 620A-620E are first subsets, and the controller 140 creates second, different subsets, and uses the second subsets to identify the degraded or faulty cell of an identified “unhealthy” subset.

For purposes of explanation, referring to the examples of FIGS. 6A and 6B, assume that subset 520A, 620B has been identified as including a degraded or faulty cell at step 506 in the FIG. 5 example. According to this example the non-overlapping subsets 520A-520E, 620A-620E may be described as first subsets, and controller 140 arranges the cells 102A-102D of the first subset 520A, 620B into second subsets 420A-420F that do include overlapping cells (e.g., reflecting each possible pair of the cells 102A-102D), as shown in the example of FIG. 4A. According to these examples, as described above with respect to FIGS. 2A and 2B, at 203, 213, the controller 140 determines metrics across the battery cells of each of the second subsets 420A-420F, and at 207 compares the metrics of each of the second subsets 420A-420F with one another as shown in FIG. 4B. As described with respect to FIG. 2A, at 207, the controller 140 identifies a degraded or faulty cell based on the comparisons of the second subsets 420A-420F with one another. For example, as described above with respect to FIG. 4B, the controller 140 may perform comparisons like 425A-425N and determine that subsets 420B, 420D, and 420F each exceed the difference threshold 445 (and/or 446) when compared to other subsets 420A, 420C, and 420E, and that the subsets 420B, 420D, and 420F each have battery cell 102C in common. As such, based on the comparisons 425A-425N, the controller 140 may identify cell 102C as degraded or faulty.

As mentioned above, in some examples, a battery stack 110 may include many battery cells 102, which may introduce significant computational complexity to determine metrics and perform comparisons. In some examples, a controller 140 may be configured to operate as described in FIG. 5, to reduce computational complexity. For example, according to the FIG. 5 example, the controller 140 first arranges the battery cells 102 in non-overlapping subsets 520A-520E or 620A-620E, which may include a larger number of battery cells 102 in some embodiments, and perform comparisons as an initial indication of battery stack 110 health to conserve energy with reduced computational complexity, and then apply the more computationally complex technique of FIGS. 4A and 4B to a relatively small number of battery cells of “unhealthy” subsets, enabling controller 140 to identify degraded or faulty cells with reduce power usage and/or reduced computational complexity.

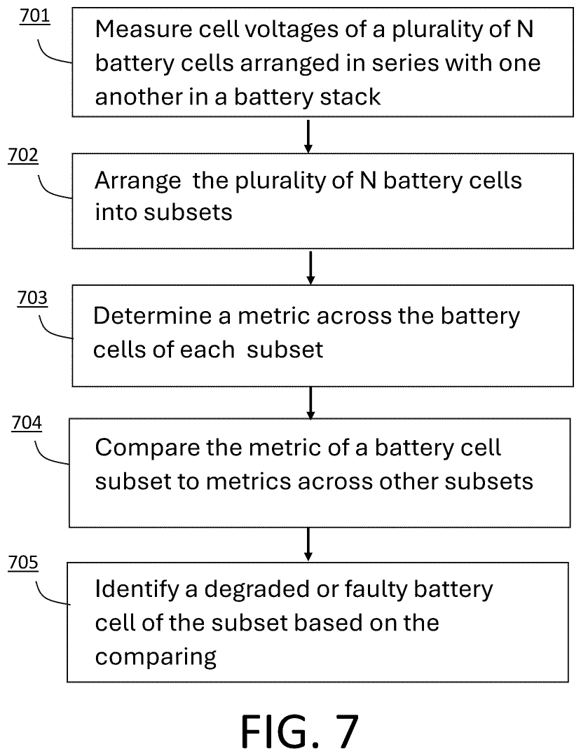

FIG. 7 is a flow diagram that depicts one example of a method of operating a battery controller according to some embodiments. As shown in FIG. 7, at 701, the method includes measuring cell voltages of a plurality of N battery cells (e.g., 102A-102T) arranged in series with one another in a battery stack (e.g., 110). Arranged in series, the plurality of N battery cells share a shared current (e.g., 112) through the battery cells. In some examples, the method further includes calculating a moving average of data points for the measured cell voltages.

In some examples, the method further includes measuring the N cell voltages during operation of the battery stack to supply energy to a load (e.g., 130). In some examples, the method further includes calculating derivatives Z_{BATT} over time of the measured cell voltages, as an approximation of impedance. According to some examples, the method further includes identifying peaks (305A-305F and 306A-306E) in the shared current through the battery stack based on the derivatives Z_{BATT}. According to these examples, the method further includes identifying a sampling window at or near the peaks, and using the measured cell voltages V_{BATT} and/or the derivatives Z_{BATT} associated with the sampling window as an approximation of impedance.

As also shown in FIG. 7, at 702, the method further includes arranging the plurality of N battery cells into subsets. The method may further include arranging the N battery cells into subsets of two or three battery cells. In some examples, the method includes arranging the plurality of N battery cells into overlapping subsets (420A-420F), where more than one subset includes the same battery cell. In other examples, the method includes arranging the plurality of N battery cells into non-overlapping subsets (e.g., 520A-520F, 620A-620F). In some examples, the method includes arranging the N battery cells into subsets (e.g., 620A-620F) of battery cells similarly situated in the battery stack. In some examples, arranging the battery cells into similarly situated subsets includes arranging battery cells that are exposed to similar external and/or environmental influences together in the subsets.

As also shown in FIG. 7, at 703, the method includes determining a metric across each of the subsets, for example based on the measured cell voltages V_{BATT}. In some examples, the method includes determining the metric across each of the substrates based on the derivative Z_{BATT} of the measured cell voltages V_{BATT} as an approximation of impedance. In some examples, the metric includes one or more of: a maximum (e.g., V_{MAX}, Z_{MAX}) across each subset, a minimum (e.g., V_{MIN}, Z_{MIN}) across each subset, a mean (e.g., V_{MEAN}, Z_{MEAN}) across each subset; a mode (e.g., V_{MODE}, Z_{MODE}) across each subset; a median (e.g., V_{MEDIAN}, Z_{MEDIAN}) across each subset, a difference (e.g., V_{DIFF}, Z_{DIFF}) between battery cells of each subset, and a standard deviation (e.g., V_{DIFF}, Z_{DIFF}) across each subset.

As also shown in FIG. 7, at 704, the method further includes comparing the metric across a subset to metrics across other subsets. As also shown in FIG. 7, at 705 the method further includes identifying a degraded or faulty battery cell of the subset based on the comparing. For example, the method may include arranging the battery cells into subsets (e.g., 420A-420F), and comparing metrics across each subset to one another to identify a degraded or faulty battery cell.

As another example, the method may include arranging the battery cells into non-overlapping subsets (e.g., 520A-520F, 620A-620F) and comparing metrics of the non-overlapping subsets to identify a subset that includes a degraded or faulty cell.

According to these examples, the method may further include performing further steps to identify a degraded or faulty cell of the identified subset. According to this example, the subsets may be first subsets, and the method includes arranging the battery cells in second subsets, determining metrics across each second subset, and comparing the determined metrics of each second subset to one another to identify which cell of the identified subset is degraded or faulty. In some examples, arranging the battery cells in second subsets includes arranging the battery cells in overlapping subsets (e.g., 420A-420F), and the method further includes using the overlapping subsets to identify a degraded or faulty cell of the identified subset.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

### Discussion of Possible Embodiments

The following are non-exclusive descriptions of possible embodiments of the present invention.

According to one example, in some aspects, a method is described. The method includes measuring cell voltages of a plurality of N battery cells arranged in series with one another in a battery stack. The method further includes arranging the plurality of N battery cells into subsets. The method further includes determining a metric across each of the subsets based on the measured cell voltages. The method further includes comparing the metric of a subset to metrics across other subsets. The method further includes identifying a degraded or faulty battery cell of the subset based on the comparing.

The method of the preceding paragraph may optionally include, additionally and/or alternatively, any one or more of the following features, configurations and/or additional steps alone or in combination with one another.

According to one example, in some aspects, the method further includes calculating a moving average of data points for the measured cell voltages. According to another example, in some aspects, the method further includes arranging the N battery cells into subsets of two or three battery cells. According to another example, in some aspects, the method further includes arranging the N battery cells into subsets of battery cells similarly situated in the battery stack. According to another example, in some aspects, the method further includes arranging battery cells exposed to similar external and/or environmental influences together in the subsets. According to another example, in some aspects, the method further includes measuring the N cell voltages during operation of the battery stack to supply energy to a load. According to another example, in some aspects, the metric across each of the subsets comprises one or more of: a maximum across each subset, a minimum across each subset, a standard deviation across each subset, a difference between respective cells across each subset, a mean across each subset, a mode across each subset, and a median across each subset. According to another example, in some aspects, the method further includes calculating a derivative over time of the measured cell voltages, and detecting peaks in a current through the battery stack based of the derivative of each measured cell value. According to another example, in some aspects, the method further includes detecting peaks that correspond to noise associated with actuation and/or recuperation of a load powered by the plurality of N battery cells. According to another example, in some aspects, the method further includes calculating derivatives over time of each the measured cell voltages as an approximation of impedance through of the plurality of N battery cells, and determining the metric across each of the subsets based on the derivatives.

According to another example, in some aspects, a battery controller is configured to measure cell voltages of a plurality of N battery cells arranged in series with one another in a battery stack. The battery controller is further configured to arrange the plurality of N battery cells into subsets. The battery controller is further configured to determine a metric across each of the subsets based on the measured cell voltages. The battery controller is further configured compare a metric across a subset to metrics across other subsets. The battery controller is further configured identify a degraded or faulty battery cell of the subset based on the comparison.

The battery controller of the preceding paragraph may optionally include, additionally and/or alternatively, any one or more of the following features, configurations and/or additional components alone or in combination with one another.

According to another example, in some aspects, the battery controller is further configured to: calculate a moving average of data points for the measured cell voltages. According to another example, in some aspects, the battery controller is further configured to arrange the N battery cells into subsets of two or three battery cells. According to another example, in some aspects, the battery controller is further configured to arrange the N battery cells into subsets of battery cells similarly situated in the battery stack. According to another example, in some aspects, the battery controller is further configured to arrange the N battery cells into subsets exposed to similar external and/or environmental influences together in the subsets. According to another example, in some aspects, the battery controller is further configured to measure the N cell voltages during operation of the battery stack to supply energy to a load. According to another example, in some aspects, the metric across each of the subsets comprises one or more of a maximum across each subset, a minimum across each subset, a standard deviation across each subset, a difference between respective cells across each subset, a mean across each subset, a mode across each subset, and a median across each subset.

According to another example, in some aspects, the battery controller is further configured to calculate a derivative over time of the measured cell voltages, and detect peaks in a current through the battery stack based on the derivative of each measured cell value. According to another example, in some aspects, the detected peaks correspond to noise associated with actuation and/or recuperation of a load powered by the plurality of N battery cells. According to another example, in some aspects, the battery controller is further configured to calculate derivatives over time of each the measured cell voltages as an approximation of impedance of the plurality of N battery cells, and determine the metric across each of the subsets based on the derivatives.

According to another example, in some aspects, a non-transitory computer-readable medium is configured to store instructions that cause a controller to measure cell voltages of a plurality of N battery cells arranged in series with one another in a battery stack. The instructions are further configured to cause the controller to arrange the plurality of N battery cells into subsets. The instructions are further configured to cause the controller to determine a metric across each of the subsets based on the measured cell voltages. The instructions are further configured to cause the controller to compare a metric of a subset to metrics across other subsets. The instructions are further configured to cause the controller to identify a degraded or faulty battery cell of the subset based on the comparison.

The computer-readable medium of the preceding paragraph may optionally include, additionally and/or alternatively, any one or more of the following features, configurations and/or additional components alone or in combination with one another.

According to one example, in some aspects, the instructions cause the controller to calculate a moving average of data points for the measured cell voltages. According to another example, in some aspects, the instructions cause the controller to arrange the N battery cells into subsets of two or three battery cells. According to another example, in some aspects, the instructions cause the controller to arrange the N battery cells into subsets of battery cells similarly situated in the battery stack. According to another example, in some aspects, the instructions cause the controller to arrange the N battery cells into subsets that include battery cells exposed to similar external and/or environmental influences together in the subsets. According to another example, in some aspects, the instructions cause the controller to measure the N cell voltages during operation of the battery stack to supply energy to a load. According to another example, in some aspects, the instructions cause the controller to determine one or more metrics selected from the group consisting of: a maximum across each subset, a minimum across each subset, a standard deviation across each subset, a difference between respective cells across each subset, a mean across each subset, a mode across each subset, and a median across each subset.

According to another example, in some aspects, the instructions cause the controller to calculate a derivative over time of the measured cell voltages, and detect peaks in a current through the battery stack based on the derivative of each measured cell value. According to another example, in some aspects, the detected peaks correspond to noise associated with actuation and/or recuperation of a load powered by the plurality of N battery cells. According to another example, in some aspects, the instructions cause the controller to calculate derivatives over time of each the measured cell voltages as an approximation of impedance of the plurality of N battery cells, and determine the metric across each of the subsets based on the derivatives.

We claim:

1. A method, comprising:
measuring cell voltages of a plurality of N battery cells arranged in series with one another in a battery stack;
arranging the plurality of N battery cells into subsets;
determining a metric across each of the subsets based on the measured cell voltages;
comparing the metric of a subset to metrics across other subsets; and
identifying a degraded or faulty battery cell of the subset based on the comparing.

2. The method of claim 1, further comprising:
calculating a moving average of data points for the measured cell voltages.

3. The method of claim 1, further comprising:
arranging the N battery cells into subsets of two or three battery cells.

4. The method of claim 1, further comprising:
arranging the N battery cells into subsets of battery cells similarly situated in the battery stack.

5. The method of claim 4, further comprising:
arranging battery cells exposed to similar external and/or environmental influences together in the subsets.

6. The method of claim 1, further comprising:
measuring the N cell voltages during operation of the battery stack to supply energy to a load.

7. The method of claim 1, wherein the metric across each of the subsets comprises one or more of:
a maximum across each subset;
a minimum across each subset;
a standard deviation across each subset;
a difference between respective cells across each subset;
a mean across each subset;
a mode across each subset; and
a median across each subset.

8. The method of claim 1, further comprising:
calculating a derivative over time of the measured cell voltages; and
detecting peaks in a current through the battery stack based of the derivative of each measured cell value.

9. The method of claim 1, further comprising:
detecting peaks that correspond to noise associated with actuation and/or recuperation of a load powered by the plurality of N battery cells.

10. The method of claim 1, further comprising:
calculating derivatives over time of each the measured cell voltages as an approximation of impedance through of the plurality of N battery cells; and
determining the metric across each of the subsets based on the derivatives.

11. A battery controller configured to:
measure cell voltages of a plurality of N battery cells arranged in series with one another in a battery stack;
arrange the plurality of N battery cells into subsets;
determine a metric across each of the subsets based on the measured cell voltages;
compare a metric across a subset to metrics across other subsets; and
identify a degraded or faulty battery cell of the subset based on the comparison.

12. The battery controller of claim 11, wherein the battery controller is further configured to:
calculate a moving average of data points for the measured cell voltages.

13. The battery controller of claim 11, wherein the battery controller is further configured to:
arrange the N battery cells into subsets of two or three battery cells.

14. The battery controller of claim 11, wherein the battery controller is further configured to:
arrange the N battery cells into subsets of battery cells similarly situated in the battery stack.

15. The battery controller of claim 14, wherein the battery controller is further configured to:
arrange the N battery cells into subsets that include battery cells exposed to similar external and/or environmental influences together.

16. The battery controller of claim 11, wherein the battery controller is further configured to:
measure the N cell voltages during operation of the battery stack to supply energy to a load.

17. The battery controller of claim 11, wherein the metric across each of the subsets comprises one or more of:
a maximum across each subset;
a minimum across each subset;
a standard deviation across each subset;
a difference between respective cells across each subset;
a mean across each subset;
a mode across each subset; and
a median across each subset.

18. The battery controller of claim 11, wherein the battery controller is further configured to:
calculate a derivative over time of the measured cell voltages; and
detect peaks in a current through the battery stack based on the derivative of each measured cell value.

19. The battery controller of claim 18, wherein the detected peaks correspond to noise associated with actuation and/or recuperation of a load powered by the plurality of N battery cells.

20. The battery controller of claim 11, wherein the battery controller is further configured to:
calculate derivatives over time of each the measured cell voltages as an approximation of impedance of the plurality of N battery cells; and
determine the metric across each of the subsets based on the derivatives.

21. A non-transitory computer-readable medium that stores instructions configured to cause a controller to:
measure cell voltages of a plurality of N battery cells arranged in series with one another in a battery stack;
arrange the plurality of N battery cells into subsets;
determine a metric across each of the subsets based on the measured cell voltages;
compare a metric of a subset to metrics across other subsets; and
identify a degraded or faulty battery cell of the subset based on the comparison.

22. The non-transitory computer-readable medium of claim 21, wherein the instructions cause the controller to:
calculate a moving average of data points for the measured cell voltages.

23. The non-transitory computer-readable medium of claim 21, wherein the instructions cause the controller to:
arrange the N battery cells into subsets of two or three battery cells.

24. The non-transitory computer-readable medium of claim 21, wherein the instructions cause the controller to:
arrange the N battery cells into subsets of battery cells similarly situated in the battery stack.

25. The non-transitory computer-readable medium of claim 24, wherein the instructions cause the controller to:
arrange battery cells exposed to similar external and/or environmental influences together in the subsets.

26. The non-transitory computer-readable medium of claim 21, wherein the instructions cause the controller to:
measure the N cell voltages during operation of the battery stack to supply energy to a load.

27. The non-transitory computer-readable medium of claim 21, wherein the metric across each of the subsets comprises one or more of:
a maximum across each subset;
a minimum across each subset;
a standard deviation across each subset;
a difference between respective cells across each subset;
a mean across each subset;
a mode across each subset; and
a median across each subset.

28. The non-transitory computer-readable medium of claim 21, wherein the instructions cause the controller to:
calculate a derivative over time of the measured cell voltages; and
detect peaks in a current through the battery stack based on the derivative of each measured cell value.

29. The non-transitory computer-readable medium of claim 28, wherein the detected peaks correspond to noise associated with actuation and/or recuperation of a load powered by the plurality of N battery cells.

30. The non-transitory computer-readable medium of claim 21, wherein the instructions cause the controller to:
calculate derivatives over time of each the measured cell voltages as an approximation of impedance of the plurality of N battery cells; and
determine the metric across each of the subsets based on the derivatives.
